(19) United States
(12) Patent Application Publication
(10) Pub. No.: US 2025/0218815 A1
(43) Pub. Date: Jul. 3, 2025

(54) APPARATUS FOR TREATING SUBSTRATE

(71) Applicant: Semes Co., Ltd, Cheonan-si (KR)

(72) Inventors: Seul Gi CHOI, Busan (KR); Eun Jung LEE, Seoul (KR); Jun Hyun LIM, Seoul (KR); Hee Jun YOUN, Goyang-si (KR)

(73) Assignee: Semes Co., Ltd, Cheonan-si (KR)

(21) Appl. No.: 19/004,669

(22) Filed: Dec. 30, 2024

(30) Foreign Application Priority Data
Dec. 29, 2023 (KR) 10-2023-0196210

(51) Int. Cl. H01L 21/67; B08B 3/08; H01L 21/677

(52) U.S. Cl. CPC H01L 21/67057; B08B 3/08; H01L 21/67706; H01L 21/6773

(57) ABSTRACT

The present invention provides an apparatus for treating a substrate. The apparatus for treating a substrate includes: a first treatment bath having a first accommodation space in which first treatment liquid is accommodated, and performing liquid treatment on a plurality of sheets of substrates; a second treatment bath having a second accommodation space in which second treatment liquid is accommodated, and performing liquid treatment on the plurality of sheets of substrates; a supporting unit fixedly installed in the second accommodation space; and a lifter unit transferring substrates between the first treatment bath and the second treatment bath, wherein the plurality of sheets of substrates is liquid-treated in a state in which the substrates are supported on the lifter unit in the first treatment bath, and the plurality of sheets of substrates is liquid-treated in a state in which the substrates are supported on the supporting unit in the second treatment bath.

### CROSS-REFERENCE TO RELATED APPLICATIONS

This application claims priority to and the benefit of Korean Patent Application No. 10-2023-0196210 filed in the Korean Intellectual Property Office on Dec. 29, 2023, the entire contents of which are incorporated herein by reference.

### TECHNICAL FIELD

The present invention relates to an apparatus for treating a substrate and, in more detail, an apparatus for treating a substrate that treats a substrate by immersing the substrate into treatment liquid.

### BACKGROUND ART

In order to manufacture a semiconductor device, a desired pattern is formed on a substrate such as a wafer through various processes such as photographing, etching, ashing, ion injection, and thin film deposition. Various treatment liquids and treatment gases are used in each of the processes, and particles and process byproducts are produced during the processes. A liquid treatment process is performed on a substrate before and after each process to remove a thin film, particles, and process byproducts on the substrate from the substrate. In general, a liquid treatment process treats a substrate with a chemical, and then removes the chemical on the substrate with a rinse solution and then performs drying treatment.

As a method of treating a substrate with treatment liquid such as a chemical and/or a rinse solution, there is a batch-type treatment method that treats a plurality of sheets of substrates in a vertical posture in batch. The batch-type treatment method performs substrate treatment by immersing a plurality of sheets of substrates in a vertical posture in batch into a treatment bath in which a chemical or a rinse solution is stored. The substrates are supported by a lifter unit having slots in which substrates and being able to transfer substrates between treatment baths. After substrates are supported on a lifter unit and treated in this state in a treatment bath storing in a chemical, the chemical and particles that are not discharged remain in the slots of the lifter unit. Thereafter, even though the substrates are treated in a treatment bath storing a rinse solution, the chemical and the particles contaminate the substrate without being discharged.

### SUMMARY OF THE INVENTION

An objective of the present invention is to provide an apparatus for treating a substrate that can efficiently perform liquid treatment on substrates.

An objective of the present invention is to provide an apparatus for treating a substrate that can prevent contamination of substrates.

An objective of the present invention is to provide an apparatus for treating a substrate that can prevent substrates from being contaminated by particles remaining on a lifter unit.

The objectives of the present invention are not limited thereto and other objectives not stated herein may be clearly understood by those skilled in the art from the following description.

The present invention provides an apparatus for treating a substrate. The apparatus for treating a substrate includes: a first treatment bath having a first accommodation space in which first treatment liquid is accommodated, and performing liquid treatment on a plurality of sheets of substrates; a second treatment bath having a second accommodation space in which second treatment liquid is accommodated, and performing liquid treatment on the plurality of sheets of substrates; a supporting unit fixedly installed in the second accommodation space; and a lifter unit transferring substrates between the first treatment bath and the second treatment bath, wherein the plurality of sheets of substrates is liquid-treated in a state in which the substrates are supported on the lifter unit in the first treatment bath, and the plurality of sheets of substrates is liquid-treated in a state in which the substrates are supported on the supporting unit in the second treatment bath.

In an embodiment, the lifter unit may be positioned in the second accommodation space when the supporting unit supports the plurality of sheets of substrates in the second accommodation space.

In an embodiment, when the substrates are liquid-treated with the supporting unit supporting the plurality of sheets of substrates in the second accommodation space, the lifter unit may be positioned to be spaced apart from the substrates under the substrates.

In an embodiment, the supporting unit may include a first supporting part and a second supporting part on each of which a plurality of slots in which the substrates are inserted is formed, and the first supporting part and the second supporting part may be installed opposite to each other.

In an embodiment, regions of the substrates supported by the first supporting part and the second supporting part may be positioned outside further than regions of the substrates supported by the lifter unit.

In an embodiment, the apparatus may further include a transfer robot transferring the lifter unit between the first treatment bath and the second treatment bath, and the lifter unit may be coupled to a side of the transfer robot.

In an embodiment, the apparatus may further include control unit, wherein the control unit may perform control such that the transfer unit conveys the lifter unit, on which the plurality of sheets of substrates is placed, from the first treatment bath to the second treatment bath.

In an embodiment, in the process in which the lifter unit on which the plurality of sheets of substrates is placed moves down in the second accommodation space in which the second treatment liquid is accommodated, the control unit may perform control such that the supporting unit supports the substrates while the lifter unit moves down, and the lifter unit further moves down to be spaced from the substrates, whereby the plurality of sheets of substrates is handed over from the lifter unit to the supporting unit.

In an embodiment, the control unit may perform control such that the lifter unit further moves down in the second accommodation space after handing over the plurality of sheets of substrates to the supporting unit and the lifter unit stands by at a lower portion of the second accommodation space when the plurality of sheets of substrates is treated in the second treatment bath.

In an embodiment, the first treatment liquid may be a chemical and the second treatment liquid may be pure water.

Further, the present invention provides an apparatus for treating a substrate. The apparatus for treating a substrate includes: a treatment bath having an accommodation space accommodating treatment liquid, and treating a plurality of sheets of substrates; a supporting unit fixedly installed in the accommodation space; and a transfer robot transferring substrates to the treatment bath, wherein the transfer robot includes a lifter unit coupled to a side of the transfer robot and supporting the plurality of sheets of substrates, the plurality of sheets of substrates is liquid-treated in a state in which the substrates are supported on the supporting unit in the treatment bath, and the plurality of sheets of substrates is transferred to the treatment bath by the lifter unit before the liquid treatment is performed in the treatment bath.

In an embodiment, the lifter unit may be positioned in the accommodation space when the supporting unit supports the plurality of sheets of substrates in the accommodation space.

In an embodiment, when the substrates are liquid-treated with the supporting unit supporting the plurality of sheets of substrates in the accommodation space, the lifter unit may be positioned to be spaced apart from the substrates under the substrates.

In an embodiment, the supporting unit may include a first supporting part and a second supporting part on each of which a plurality of slots in which the substrates are inserted is formed, the first supporting part and the second supporting part may be installed opposite to each other, and regions of the substrates supported by the first supporting part and the second supporting part may be positioned outside further than regions of the substrates supported by the lifter unit.

In an embodiment, the apparatus may further include control unit, wherein the control unit may perform control such that the transfer robot transfers the lifter unit, on which the plurality of sheets of substrates is placed, to the treatment bath, and the supporting unit supports the substrates while the lifter unit moves down and the lifter unit further moves down to be spaced from the substrates in the process in which the lifter unit moves down in the accommodation space in which the treatment liquid is accommodated, whereby the plurality of sheets of substrates is handed over from the lifter unit to the supporting unit.

In an embodiment, the apparatus may further include control unit, wherein the control unit may perform control such that the lifter unit further moves down in the accommodation space after handing over the plurality of sheets of substrates to the supporting unit and the lifter unit stands by at a lower portion of the accommodation space when the plurality of sheets of substrates is treated in the treatment bath.

In an embodiment, the treatment liquid may be pure water.

Further, the present invention provides an apparatus for treating a substrate. The apparatus for treating a substrate includes: a first treatment bath having a first accommodation space in which first treatment liquid is accommodated, and performing liquid treatment on a plurality of sheets of substrates; a second treatment bath having a second accommodation space in which second treatment liquid is accommodated, and performing liquid treatment on the plurality of sheets of substrates; a supporting unit fixedly installed in the second accommodation space; and a transfer robot transferring substrates between the first treatment bath and the second treatment bath, wherein the transfer robot includes a lifter unit coupled to a side of the transfer robot and supporting the plurality of sheets of substrates, the plurality of sheets of substrates is liquid-treated in a state in which the substrates are supported on the lifter unit in the first treatment bath, the plurality of sheets of substrates is liquid-treated in a state in which the substrates are supported on the supporting unit in the second treatment bath, the lifter unit is positioned in the second accommodation space when the supporting unit supports the plurality of sheets of substrates in the second accommodation space, the second supporting unit includes a first supporting part and a second supporting part on each of which a plurality of slots is formed, the first supporting part and the second supporting part may be installed opposite to each other, and regions of the substrates supported by the first supporting part and the second supporting part may be positioned outside further than regions of the substrates supported by the lifter unit.

In an embodiment, the control unit may perform control such that the transfer robot transfers the lifter unit, on which the plurality of sheets of substrates is placed, from the first treatment bath to the second treatment bath, and the supporting unit supports the substrates while the lifter unit moves down and the lifter unit further moves down to be spaced from the substrates in a process in which the lifter unit, on which the plurality of sheets of substrates is placed, moves down in the second accommodation space in which the second treatment liquid is accommodated, whereby the plurality of sheets of substrates is handed over from the lifter unit to the supporting unit; and the control unit may perform control such that the lifter unit further moves down in the second accommodation space after handing over the plurality of sheets of substrates to the supporting unit and the lifter unit stands by at a lower portion of the second accommodation space when the plurality of sheets of substrates is treated in the second treatment bath.

In an embodiment, the first treatment liquid may be a chemical and the second treatment liquid may be pure water.

According to an embodiment, it is possible to efficiently perform liquid treatment on substrates.

Further, according to an embodiment, it is possible to prevent contamination of substrates.

Further, according to an embodiment, it is possible to prevent substrates from being contaminated by particles remaining on the lifter unit.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a schematic view of an apparatus for treating a substrate according to an embodiment of the present invention seen from above.

FIG. 2 is a view schematically showing the structure of the second chemical liquid bath of FIG. 1.

FIG. 3 is a view schematically showing the structure according to an embodiment of the second rinse bath of FIG. 1.

FIG. 4 is a perspective view showing the supporting unit of FIG. 3.

FIG. 5 is a perspective view showing a lifter unit of the second batch transfer unit of FIG. 1.

FIG. 6 briefly shows that substrates are treated in the second chemical liquid bath of FIG. 2.

FIG. 7 briefly shows that the second batch transfer unit transfers substrates from the second chemical liquid bath to the second rinse bath.

FIG. 8 briefly shows the appearance at a time point at which substrates are handed over to the supporting unit from the lifter unit in the second rinse bath of FIG. 2.

FIG. 9 briefly shows that substrates are treated in the second chemical liquid bath of FIG. 2.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Further, components that transfer substrates W to be described below, for example, transfer units or transfer robots may be referred to as transfer modules.

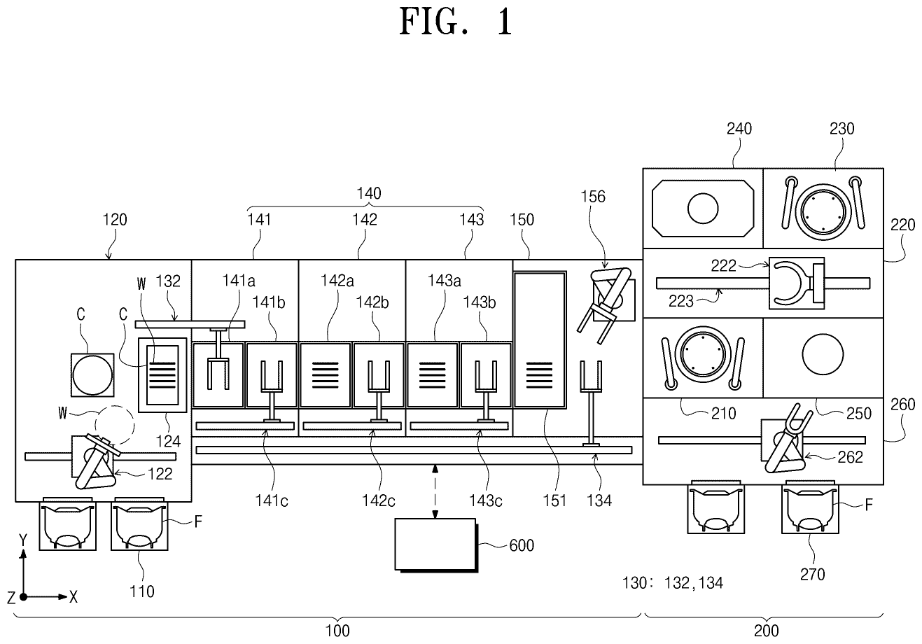

Hereafter, embodiments of the present invention are described with reference to FIG. 1 to FIG. 9.

FIG. 1 is a schematic view of an apparatus for treating a substrate according to an embodiment of the present invention seen from above.

Referring to FIG. 1, an apparatus 10 for treating a substrate may include a first process performing part 100, a second process performing part 200, and a control unit 600. The first process performing part 100 and the second process performing part 200 may be arranged in a line when seen from above. Hereafter, the direction in which the first process performing part 100 and the second process performing part 200 are arranged is referred to as a first direction X, a direction perpendicular to the first direction X when seen from above is referred to as a second direction Y, and a direction perpendicular to the first direction X and the second direction Y is referred to as a third direction Z.

The first process performing part 100 can perform liquid treatment on a plurality of substrates W all at once in a batch type. For example, liquid treatment may be washing treatment that removes unnecessary films or particles on the substrates W. The first process performing part 100 can simultaneously treat a plurality of substrates W with a pattern surface of the substrates W positioned in a direction perpendicular to the ground.

The first process performing part 100 may include a first load port unit 110, an index chamber 120, a transfer unit 130, a liquid treatment chamber, and a posture changing unit 150.

The first load port unit 110 may include at least one or more load ports. A conveying container F in which a substrate W is accommodated may be placed in the load ports of the first load port unit 110. A plurality of substrates W may be accommodated in the conveying container F. For example, 25 sheets of substrates W may be accommodated in the conveying container F. The conveying container F may be a cassette, a FOD, or a FOUP. The conveying container F can be loaded into the first load port unit 110 by a container transfer device. The substrates W accommodated in the conveying container F that is placed in the first load port unit 110 may be non-treated substrates W. The non-treated substrates W, for example, may be substrates W that have not been treated or substrates W that have been partially treated but require liquid treatment.

Further, a container F in which non-treated substrates W are accommodated can be placed in the first load port unit 110. That is, the first load port unit 110 can serve to load substrates W that require treatment.

The first load port unit 110 may be coupled to the index chamber 120. The index chamber 120 and the first load port unit 110 may be arranged in the second direction Y. The first index chamber 120 may include an index robot 122 and a posture changing unit 124. The index robot 122 can unload substrates W that have not been treated or require treatment out of the container F seated in the first load port unit 110. The first transfer robot 122 can unload substrates W from the container F and load the substrates W into an accommodation container C provided in the first index chamber 120. The first transfer robot 122 may have a batch hand that can simultaneously hold and transfer a plurality of sheets (e.g. 25 sheets) of substrates W.

The accommodation container C may have a substantially box shape. The accommodation container C may have an accommodation space therein. A plurality of substrates W may be accommodated in the accommodation space of the accommodation container C. For example, 50 sheets of substrates W may be accommodated in the accommodation space of the accommodation container C. The accommodation container C may have a box shape of which at least two or more surfaces of the surfaces thereof are open. A supporting member that supports/holds substrates W may be provided in the accommodation space of the accommodation container C.

When substrates W unloaded from the conveying container F finish being loaded into the accommodation container C, the substrates W can be transferred to the posture changing unit 124 disposed in the index chamber 120 by a transfer part not shown. The posture changing unit 124 can rotate the accommodation container C. For example, the posture changing unit 124 can rotate the accommodation container C such that an open portion of the accommodation container C faces up. When the accommodation container C is rotated such that an open portion faces up, the posture of the substrates W accommodated in the accommodation container C can be changed from a horizontal posture to a vertical posture. The horizontal posture may mean that the upper surface of a substrate (for example, a surface having a pattern formed thereon) is parallel with an X-Y plane (i.e., the ground) and the vertical position may mean that the upper surface of a substrate W is parallel with an X-Z plane or a Y-Z plane (i.e., a surface perpendicular to the ground).

The transfer unit 130 may include a first transfer unit 132 transferring substrates W between the index chamber 120 and a batch treatment unit 140 and a second transfer unit 134 transferring substrates W between the batch treatment unit 140 and the posture changing unit 150 to be described below.

The first transfer unit 132 may include a rail extending in the first direction X and a hand configured to be able to transfer a plurality of substrates W at a time. The first transfer unit 132 can hold substrates W with the posture changed in the posture changing unit 124 and transfer the held substrates W to a liquid treatment chamber. For example, the first transfer unit 132 can transfer substrates W with the posture changed at the posture changing unit 124 to any one treatment bath selected from batch treatment baths 141a to 143b of the batch treatment unit 140. The second transfer unit 134 may include a rail extending in the first direction X and a hand configured to be able to transfer a plurality of substrates W at a time.

The second transfer unit 134 may be configured to be able to transfer substrates W between a first batch treatment unit 141 and a second batch treatment unit 142, and a third batch treatment unit 143 of the batch treatment unit 140 to be described below. Further, the second transfer unit 134 may be configured to be able to transfer substrates W between the batch treatment unit 140 and the posture changing unit 150.

The liquid treatment chamber performs liquid treatment on substrates W by supplying treatment liquid to the substrates W.

According to an example, the liquid treatment chamber is provided as the batch treatment unit 140 that performs liquid treatment on a plurality of substrates W at a time. Liquid treatment can be performed on a plurality of substrates W at a time using treatment liquid in the batch treatment unit 140. The treatment liquid that is used in the batch treatment unit 140 may be a chemical and/or a rinse solution. For example, the chemical may be a chemical that has the property of strong acid or strong base. For example, the chemical may be appropriately selected from an Ammonia-Hydrogen Peroxide Mixture (APM), a Hydrochloricacid-Hydrogen Peroxide Mixture (HPM), a Hydrofluoricacid-Hydrogen Peroxide Mixture (FPM), Diluted Hydrofluoric acid (DHF), Diluted Sulfuric acid Peroxide (DSP), a chemical removing SiN, a chemical containing phosphoric acid, a chemical containing sulfuric acid, or the like. The rinse solution may be water. For example, the rinse solution may be pure water.

The batch treatment unit 140 may include a first batch treatment unit 141, a second batch treatment unit 142, and a third batch treatment unit 143.

The first batch treatment unit 141, the second batch treatment unit 142, and the third batch treatment unit 143 each include a chemical liquid bath, a rinse bath, and a batch transfer unit transferring substrates W between them.

In each batch treatment unit, substrates W are treated with first treatment liquid in the chemical liquid bath and then treated with second treatment liquid in the rinse bath. The first treatment liquid may be a chemical and the second treatment liquid may be a rinse solution.

Substrates W changed in posture by the posture changing unit 124 and accommodated in the accommodation container C and substrates W accommodated in the batch treatment bath of the batch treatment unit 140 may be arranged in parallel in the second direction Y when seen from above.

Further, substrates W accommodated in the batch treatment baths 141a to 143b of the batch treatment unit 140 and substrates W accommodated in a posture changing bath 151 of the posture changing unit 150 may be arranged in parallel in the second direction Y when seen from above. That is, the supporting units 320 of each of the batch treatment baths 141a to 143b may be arranged in parallel in the first direction X when seen from above.

The first batch treatment unit 141 may include a first chemical liquid bath 141a, a first rinse bath 141b, and a first batch transfer unit 141c.

It is possible to simultaneously perform liquid treatment on a plurality of sheets of substrates W with a chemical such as DHF in the first chemical liquid bath 141a. It is possible to simultaneously perform liquid treatment on a plurality of sheets of substrates W with a rinse solution in the first rinse bath 141b. However, the present invention is not limited thereto and the treatment liquid that is used in the first chemical liquid bath 141a may be variously changed to treatment liquid selected from the treatment liquids described above.

Thin films on substrates W, remaining membrane materials on the substrates W, foreign substances on the substrates W, or the like can be removed in the first chemical liquid bath 141a. It is possible to simultaneously treat a plurality of sheets of substrates W with a rinse solution such as pure water in the first rinse bath 141b. A chemical remaining on substrates W after used to treat the substrates W in the first chemical liquid bath 141a is removed from the substrates W in the first rinse bath 141b.

The first batch transfer unit 141c may be configured to be able to transfer substrates W between the first chemical liquid bath 141a and the first rinse bath 141b.

The second batch treatment unit 142 may include a second chemical liquid bath 142a, a second rinse bath 142b, and a second batch transfer unit 142c.

It is possible to simultaneously perform liquid treatment on a plurality of sheets of substrates W with a chemical containing phosphoric acid in the second chemical liquid bath 142a.

It is possible to simultaneously treat a plurality of sheets of substrates W with a rinse solution in the second rinse bath 142b. However, the present invention is not limited thereto and the treatment liquid that is used in the second chemical liquid bath 142a may be variously changed to treatment liquid selected from the treatment liquids described above.

The second batch transfer unit 142c may be configured to be able to transfer substrates W between the second chemical liquid bath 142a and the second rinse bath 142b.

The third batch treatment unit 143 may include a third chemical liquid bath 143a, a third rinse bath 143b, and a third batch transfer unit 143c.

It is possible to simultaneously perform liquid treatment on a plurality of sheets of substrates W with a chemical containing phosphoric acid in the third chemical liquid bath 143a. It is possible to simultaneously treat a plurality of sheets of substrates W with a rinse solution in the third rinse bath 143b. However, the present invention is not limited thereto and the treatment liquid that is used in the third chemical liquid bath 143a may be variously changed to treatment liquid selected from the treatment liquids described above.

The third batch transfer unit 143c may be configured to be able to transfer substrates W between the third chemical liquid bath 143a and the third rinse bath 143b.

According to an embodiment, the second batch treatment unit 142 and the third batch treatment unit 143 can treat substrates W with the same chemical and the first batch treatment unit 141 can treat substrates W with a chemical different from that of the second batch treatment unit 142 or the third batch treatment unit 143. Hereafter, it is exemplarily described that the second batch treatment unit 142 and the third batch treatment unit 143 treat substrates W with a phosphoric acid solution and the first batch treatment unit 141 treats substrates W with any one chemical of the chemicals exemplified above.

It is shown in FIG. 1 that the batch treatment unit 140 includes the first batch treatment unit 141, the second batch treatment unit 142, and the third batch treatment unit 143, but the present invention is not limited thereto.

For example, additional batch treatment units may be further provided. Additional batch treatment units can treat substrates W with a chemical the same as or different from that of the first disposition treatment unit 141, the second disposition treatment unit 142, or the third batch treatment unit 143.

Selectively, the batch treatment unit 140 may include only the second batch treatment unit 142 and the third batch treatment unit 143 without the first batch treatment unit 141.

Selectively, the batch treatment unit 140 may include only the second batch treatment unit 142.

Hereafter, the structure of the batch treatment unit 140 is described.

The first batch treatment unit 141, the second batch treatment unit 142, and the third batch treatment unit 143 are provided in the same or similar structures. The following describes the second batch treatment unit 142 as the main focus.

The second batch treatment unit 142 may include a second chemical liquid bath 142a, a second rinse bath 142b, and a second batch transfer unit 142c.

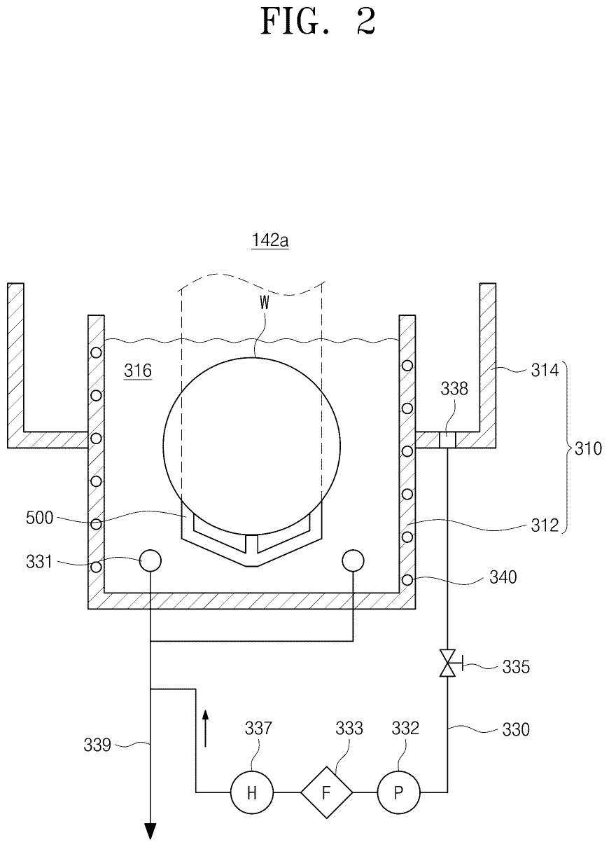

FIG. 2 is a view schematically showing the structure of the second chemical liquid bath of FIG. 1.

The second chemical liquid bath 142a has a first treatment bath 310, a circulation line 330, and a heating unit 340.

The first treatment bath 310 may have an inner bath 312 and an outer bath 314. The inner bath 312 has a first accommodation space 316 therein. The inner bath 312 may have a box shape with open top. For example, the inner bath 312 may have a rectangular prism shape. Treatment liquid may be accommodated in the first accommodation space 316. The treatment liquid may be a chemical. The treatment liquid may be a phosphoric acid solution.

While substrates W are treated with treatment liquid in the first accommodation space 316, the substrates W can be supported by a lifter unit 500. The lifter unit 500 will be described below.

The outer bath 314 is provided to surround the inner bath 312 outside the inner bath 312. For example, the outer bath 314 has a rectangular prism shape similar to the inner bath 312. The outer bath 314 is provided in a size larger than the inner bath 312. The outer bath 314 accommodates treatment liquid overflowing from the inner bath 312. A discharge hole 338 for discharging treatment liquid is formed at the outer bath 314. The discharge hole 338 is formed through the bottom of the outer bath 314. Treatment liquid overflowing from the inner bath 312 to the outer bath 314 is discharged to the circulation line 330 to be described below through the discharge hole 338.

The circulation line 330 circulates treatment liquid in the first treatment bath 310. The circulation line 330 performs a series of treatment liquid circulation process of supplying treatment liquid to the first treatment bath 310, filtering the treatment liquid discharged from the first treatment bath 310, and resupplying or draining the treatment liquid.

A liquid supply pipe 331, a pump 332, a filter 333, a valve 335, and a heater 337 are installed in the circulation line 330. The pump 332 provides dynamic pressure to treatment liquid such that treatment liquid circulates along the circulation line 330.

The liquid supply pipe 331 supplies treatment liquid to the first treatment bath 310. A portion of the liquid supply pipe 331 is disposed in the first treatment bath 310. A portion of the liquid supply pipe 331 is disposed at a lower portion of the first accommodation space 316 of the inner bath 312.

A plurality of liquid supply pipes 331 may be provided. In this case, the liquid supply pipes 331 may be disposed in parallel with each other. The liquid supply pipes 331 are positioned lower than substrates W that are treated in the first accommodation space 316. The liquid supply pipes 331 may be positioned lower than the lifter unit 500.

The filter 333 removes foreign substances in treatment liquid circulating in the circulation line 330.

The valve 335 opens and closes the circulation line 330. When the valve 335 is opened, treatment liquid in the treatment bath 310 keeps circulating along the circulation line 330.

The heater 337 can heat treatment liquid that is supplied to the first treatment bath 310 to a set temperature.

The heating unit 340 can heat the treatment liquid accommodated in the first accommodation space 316. The heating unit 340 may be disposed at a side of the inner bath 312. The heating unit 340 may be embedded in the wall of the inner bath 312 or may be disposed in a housing of the first treatment bath 310 not shown.

Selectively, a gas supply unit (not shown) that supplies gas to the first accommodation space 316 may be further included, and a gas supply pipe (not shown) that supplies gas to the first accommodation space 316 may be installed. The gas supply pipe may be disposed at a lower portion of the first accommodation space 316.

The second rinse bath 142b may have a structure similar to the second chemical liquid bath 142a. For example, the second rinse bath 142b also includes a second treatment bath 410 having a second accommodation space 316 and treatment liquid can be accommodated in the second accommodation space 316. The treatment liquid may be a rinse solution.

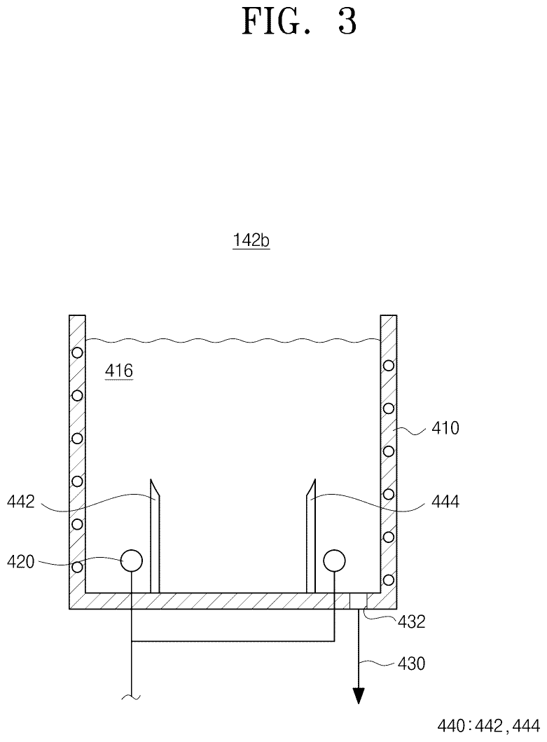

Alternatively, as shown in FIG. 3, the second rinse bath 142b, unlike the second chemical liquid bath 142a, may be configured as a single treatment bath without division into an outer bath and an inner bath.

FIG. 3 is a view schematically showing the structure according to an embodiment of the second rinse bath of FIG. 1.

The second rinse bath 142b has a second treatment bath 410, a liquid supply pipe 420, a discharge line 430, and a supporting unit 440.

The second treatment bath 410 has a second accommodation space 416 therein. The second treatment bath 410 may have a box shape with open top. For example, the second treatment bath 410 may have a rectangular prism shape. Treatment liquid may be accommodated in the second accommodation space 416. The treatment liquid may be a rinse solution. The treatment liquid may be pure water.

The liquid supply pipe 420 is connected with a liquid supply source not shown, thereby supplying treatment liquid to the second accommodation space 416. A portion of the liquid supply pipe 331 is disposed in the second treatment bath 410. That is, a portion of the liquid supply pipe 331 is disposed at a lower portion of the second accommodation space 416.

The discharge line 430 can discharge treatment liquid in the second accommodation space 416 through a discharge hole 432 installed at the lower end of the second accommodation space 416.

The supporting unit 440 can support a substrate M. The supporting unit 440 may be configured to be able to support a plurality of substrates W. For example, the supporting unit 440 may be configured to be able to support 25 or 50 sheets of substrates W.

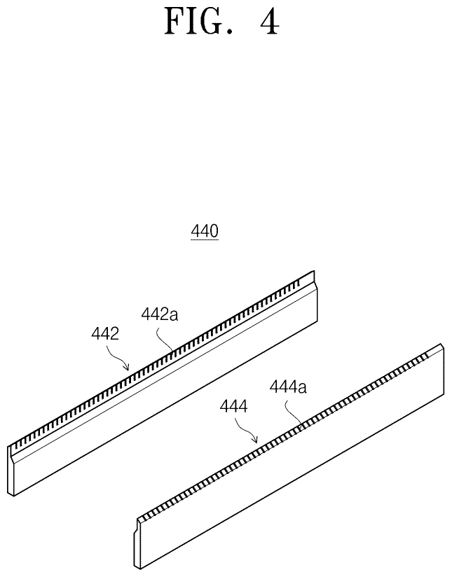

FIG. 4 is a perspective view showing the supporting unit of FIG. 3.

Referring to FIG. 3 and FIG. 4, the supporting unit 440 includes a first supporting part 442 and a second supporting part 444 fixedly installed at a lower portion of the second accommodation space 416.

The first supporting part 442 and the second supporting part 444 are disposed to face each other. The first supporting part 442 and the second supporting part 444 are installed to be spaced apart from each other opposite to each other at the same height. The first supporting part 442 and the second supporting part 444 may be installed opposite to each other to be positioned at the same distances from the center of the second accommodation space 416.

The first supporting part 442 and the second supporting part 444 support the side end of a substrate W. In this case, the side end of a substrate W means the region between the side ends and the lower end of the substrate W of the ends of the substrate W erected in a vertical state.

The region of a substrate W supported by the first supporting part 442 and the second supporting part 444 is positioned outside further than the region of a substrate W supported by the lifter unit 500 to be described below.

That is, when seen from above, the first supporting part 442 and the second supporting part 444 are positioned outside further than a first support 512 and a second support 514 of the lifter unit 500.

The first supporting part 442 and the second supporting part 444 may have a rectangular plate shape. Pluralities of slots 442a and 444a are respectively formed on the upper ends of the first supporting part 442 and the second supporting part 444 with predetermined gaps in the longitudinal direction of the first supporting part 442 and the second supporting part 444.

Edges of substrates W can be inserted in the slots 442a and 444a. The slots 442a and 444a are formed in a number corresponding to the number of substrates W. For example, 25 or 50 slots may be formed.

Referring to FIG. 1 again, the second batch transfer unit 142c may be configured to be able to transfer substrates W between the second chemical liquid bath 142a and the second rinse bath 142b. The second batch transfer unit 142c includes the lifter unit 50 supporting substrates.

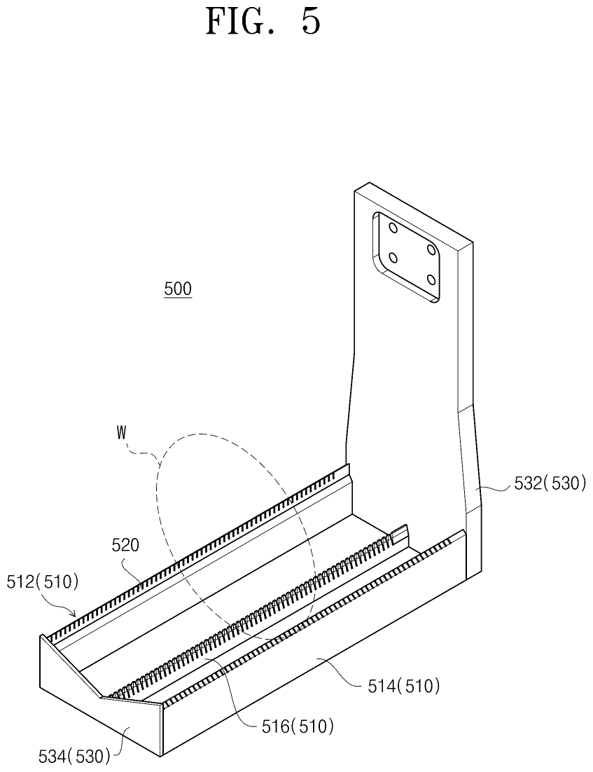

FIG. 5 is a perspective view showing the lifter unit of the second batch transfer unit of FIG. 1.

Referring to FIG. 2 and FIG. 5, the lifter unit 500 can support substrates W. The lifter unit 500 can support substrates in the first accommodation space 316 of the second chemical liquid bath 142a and can transfer substrates W between the second chemical liquid bath 142a and the second rinse bath 142b by moving up and down. The lifter unit 500 may be configured to be able to support a plurality of substrates W.

The lifter unit 500 has a support 510 and a fixing plate 530.

A plurality of supports 510 is provided. 2 to 5 supports 510 may be provided to stably support substrates W. According to an embodiment, a first support 512, a second support 514, and a third support 516 are provided. The first support 512, the second support 514, and the third support 516 each have a rod shape. The first support 512 and the second support 514 are positioned to be spaced apart from each other opposite to each other at the same height. The first support 512 and the second support 514 support the side end of a substrate W. The first support 512 and the second support 514 are disposed to face each other.

The third support 516 is positioned between the first support 512 and the second support 514 when seen from above. The third support 516 is disposed at a lower position than the first support 512. The third support 516 supports the lower end of a substrate W.

A plurality of slots 520 is formed at the upper ends of the supports 512, 514, and 516 with predetermined gaps in the longitudinal direction of the supports 512, 514, and 516. Edges of substrates W can be inserted in the slots 520. The slots 520 are formed in a number corresponding to the number of substrates W. For example, 25 or 50 slots 520 may be formed.

The fixing plate 530 fixes the supports 512, 514, and 516 to each other. Two fixing plates 530 are provided. First ends of the supports 512, 514, and 516 are coupled to a first fixing plate 532. Second ends of the supports 512, 514, and 516 are coupled to a second fixing plate 534.

The first fixing plate 532 is coupled to an end of the second batch transfer unit 142c.

Hereafter, an embodiment of a method for treating substrates W in the second batch treatment unit of FIG. 1 is described with reference to FIG. 1 to FIG. 8.

The second batch transfer unit 142c to which the lifter unit 500 supporting a substrate W is coupled at a side transfers substrates W to the second chemical liquid bath 142a. A plurality of sheets of substrates are supported on the lifter unit of the second batch transfer unit 142c and loaded in this state into the second chemical liquid bath 142a filled with a phosphoric acid solution.

The substrates W are immersed into the phosphoric acid solution in the first treatment bath 310 of the second chemical liquid bath 142a. The phosphoric acid solution is accommodated in a heated state in the first treatment bath 310.

The phosphoric acid solution in the second chemical liquid bath 142a circulates through the circulation line 330, whereby the substrates W are treated with the phosphoric acid solution.

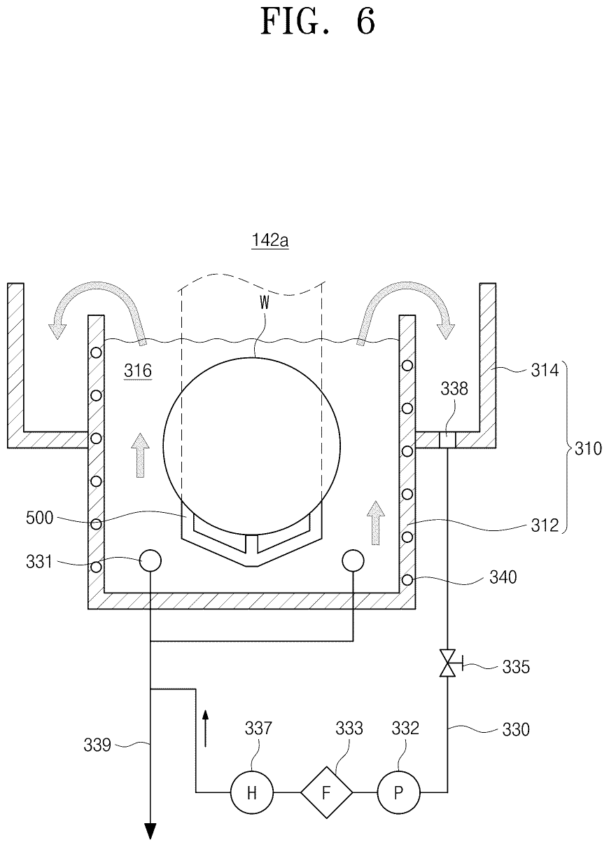

FIG. 6 briefly shows the appearance in which substrates are treated in the second chemical liquid bath of FIG. 2.

The lifter unit 500 supports substrates W in the first accommodation space 316 and the substrates W are treated with treatment liquid in the state in which they are supported by the lifter unit 500.

A phosphoric acid solution supplied to the accommodation space 316 through the liquid supply pipe 331 flows upward in the first accommodation space 316 and then overflows to the outer bath 314.

The phosphoric acid solution discharged through the discharge hole 338 of the outer bath 314 moves along the circulation line 330 and circulates at a set temperature through the pump 332, the filter 333, the valve 335, and the heater 337. While the phosphoric acid solution flows through the circulation line 330, foreign substances are removed by the filter 333 and the phosphoric acid solution keeps being heated to the set temperature.

When treatment with the phosphoric acid solution is finished, the second batch transfer unit 142c transfers the substrates W to the second rinse bath 142b with the accommodation space 316 filled with the phosphoric acid solution.

Unlike, the phosphoric acid solution is drained through a drain hole 339 of the circulation line 330 and then the second batch transfer unit 142c may transfer the substrates W to the second rinse bath 142b.

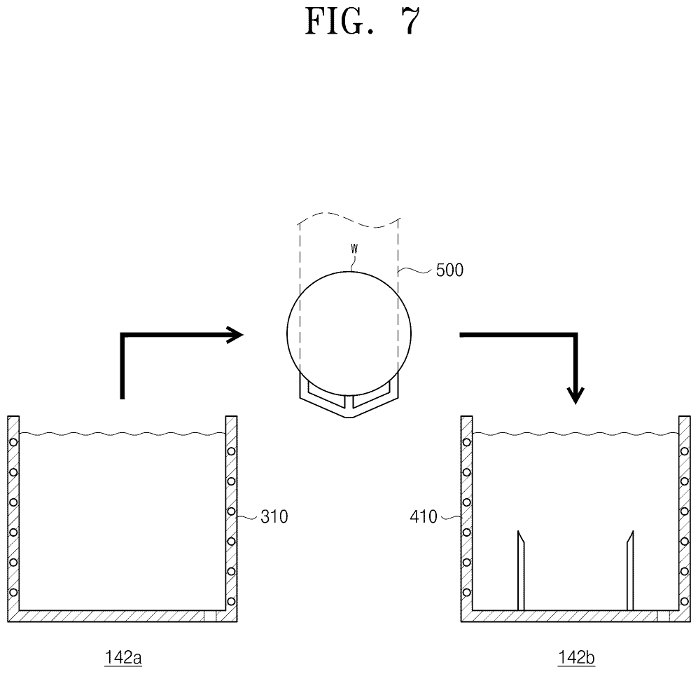

FIG. 7 briefly shows that the second batch transfer unit transfers substrates from the second chemical liquid bath to the second rinse bath.

Referring to FIG. 7, substrates W are supported by the lifter unit 500 of the second batch transfer unit 142c and transferred in this state to the second rinse bath 142b from the second chemical liquid bath 142a.

The substrates W are transferred to the second ring bath 142b by the second batch transfer unit 142c and loaded into the second treatment bath 410 filled with pure water. The substrates W supported on the lifter unit 500 are immersed in this state into the pure water in the second accommodation space 416 of the second treatment bath 410.

In this case, the lifter unit 500 continuously moves down in the second accommodation space 416. In the process in which the lifter unit 500 continuously moves down in the second accommodation space 416, the supporting unit 440 supports the substrates W and the lifter unit 500 is further moved down and spaced from the substrates W. Accordingly, the plurality of sheets of substrates W supported by the lifter unit 500 are handed over to the supporting unit 400 from the lifter unit 500.

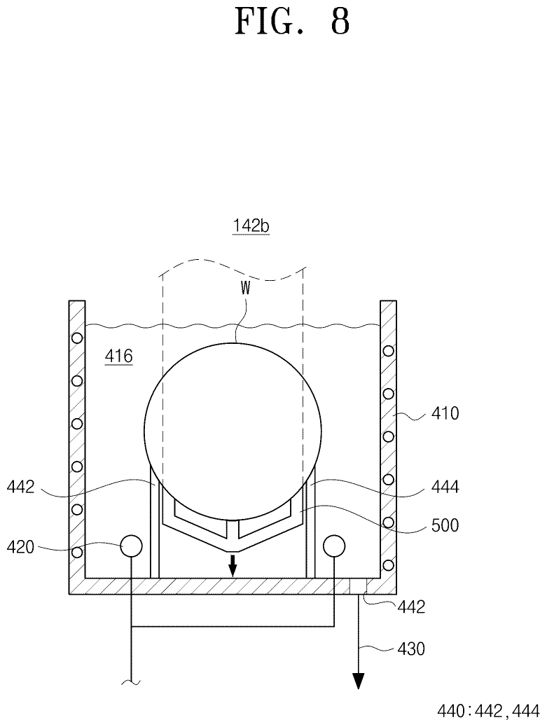

FIG. 8 briefly shows the appearance at a time point at which substrates are handed over to the supporting unit from the lifter unit in the second rinse bath of FIG. 2.

Further referring to FIG. 8, in the process in which the lifter unit 500 moves down while supporting a plurality of sheets of substrates W, the first supporting part 442 and the second supporting part 444 of the supporting unit 440 support the side end of each of the substrates W. Thereafter, as the lifter unit 500 further moves down, the lifter unit 500 is spaced from the substrates W and moved to the lower portion of the second accommodation space 416. The substrates W are handed over to the supporting unit 440 from the lifter unit 500 and are supported by the first supporting part 442 and the second supporting part 444 of the supporting unit 440.

The lifter unit 500 further moves down to the lower portion of the second accommodation space 416 after handing over the substrates W to the supporting unit 440.

As described above, the regions of substrates supported by the first supporting part 442 and the second supporting part 444 are positioned outside further than the regions of the substrates W supported by the lifter unit 500, and when see from above, the first supporting part 442 and the second supporting part 444 are positioned outside further than the first support 512 and the second support 514 of the lifter unit 500, so the lifter unit 500 is not interfered with by the supporting unit 440 when it further moves down.

Thereafter, the pure water in the second rinse bath 142b treats the substrates W.

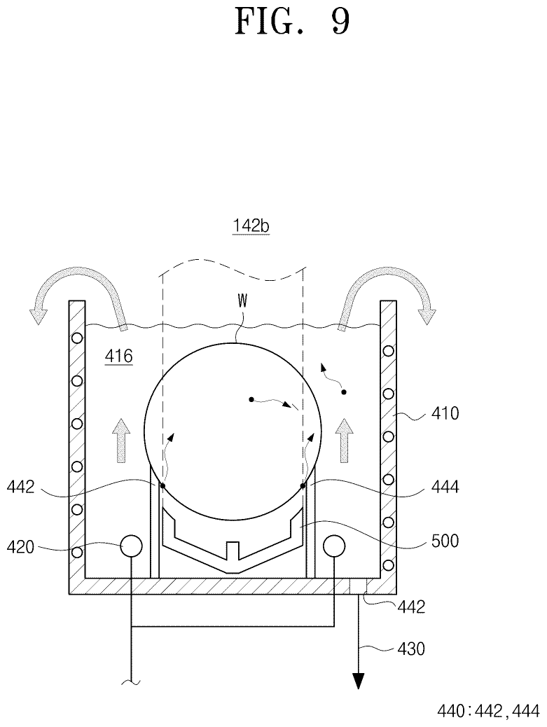

FIG. 9 briefly shows that substrates are treated in the second chemical liquid bath of FIG. 2.

Referring to FIG. 9, substrates W are treated with pure water in the stat in which they are supported by the supporting unit 440. While the substrates W are treated with pure water, the lifter unit 500 enters a standby state at the lower portion of the second accommodation space 416. In this case, the lifter unit 500 is positioned to be spaced apart from the substrates W under the substrates W.

The pure water supplied to the second accommodation space 416 through the liquid supply pipe 420 washes out the phosphoric acid solution and particles remaining on the substrates W in the second accommodation space 416 and overflows to the outside from the second treatment bath 410.

In the process in which the lifter unit 500 treats substrates W in the second chemical liquid bath 142a and loads the substrate to the second rinse bath 142b, phosphoric acid and particles remain on the lifter unit 500. In particular, there are remaining phosphoric acid and particles in the plurality of slots 520 formed on the upper ends of the supports 512, 514, and 516.

Substrates W treated with pure water in the state in which they are supported by the supporting unit 440, and in this process, the lifter unit 500 stands by at the lower portion of the second accommodation space 416, so the phosphoric acid solution and particles remaining in the plurality of slots 520 formed on the supports 512, 514, and 516 of the lifter unit 500 can also be washed out. FIG. 9 shows the appearance when particles remaining on substrates W are washed out.

Since the phosphoric acid solution and particles remaining in the plurality of slots 520 formed on the supports 512, 514, and 516 of the lifter unit 500 are washed out together, it is possible to prevent contamination of the lifter unit 500 and prevent the phosphoric acid and particles remaining in the lifter unit 500 from contaminating other substrates W.

Further, since the lifter unit 500 hands over substrates W to the supporting unit 440 while transferring the substrates W to the second rinse bath 142b, the contact time of the phosphoric acid and particles remaining in the lifter unit 500 with the substrates W decreases and it is possible to prevent the remaining phosphoric acid or particles that are stagnant in the lifter unit 500 from contaminating the substrates W. Accordingly, it is possible to prevent contamination of substrates and efficiently treat substrates with liquid.

After the treatment with the pure water is finished, the second transfer unit 134 can unload and transfer the substrates W to the posture changing bath 151 with the second accommodation space 416 of the second ring bath 142b filled with pure water. Alternatively, after substrates W finish being treated with pure water, the lifter unit 500 can move up and receive the substrates W from the supporting unit 440 and the second transfer unit 134 can unload and transfer the substrates W to the posture changing bath 151.

After the substrates are unloaded out of the second accommodation space 416, the lifter unit 500 ascends and moves, and receives other substrates W from the second transfer unit 134, whereby it is possible to perform a series of processes of treating substrates W in the second chemical liquid bath 142a.

When the substrates W are transferred to the posture changing bath 151, spray liquid treatment may be additionally performed on the substrates W to maintain wetting of the substrates W.

The rinsed substrates W are moved to the posture changing unit 150 and are transferred to a standby chamber 210 in a horizontal posture by a single-type transfer robot 156 that changes the posture of substrates, and a single-type treating step can be additionally performed. In the single-type treating step, treatment can be performed on a single substrate W in a horizontal posture. The single-type treating step may include a liquid treating step of performing liquid treatment on substrates W in a single type and may include a drying step of drying substrates W in a single type. The liquid treating step can be performed in the liquid treatment chamber 230 when substrates W temporarily kept in the standby chamber 210 are transferred to the liquid treatment chamber 230. The drying step can be performed in the drying chamber 240 when the substrates W liquid-treated in the liquid treating step are transferred to the drying chamber 240. The substrates W that have undergone the single-type treating step are transferred to the buffer unit 250 and then can be transferred to the conveying container F placed in the second load port unit 270 by a second transfer robot 262 of a second transfer chamber 260, and a transfer device such as an OHT can hold and unload the conveying container F placed in the second load port unit 270 from the apparatus for treating a substrate. Detailed description of this process is omitted.

A control unit 600 can control the apparatus 10 for treating a substrate. For example, the control unit 600 can control the components of the apparatus 10 for treating a substrate. For example, the control unit 600 can control the apparatus 10 for treating a substrate such that the apparatus 10 for treating a substrate can perform a process of treating substrates W.

For example, the control unit 600 can control at least one or more of the first load port unit 110, the index chamber 120, the transfer unit 130, the batch treatment unit 140, the posture changing unit 150, the buffer chamber 210, the first transfer chamber 220, the liquid treatment chamber 230, the drying chamber 240, and the second transfer chamber 260.

Further, the control unit 600 may include: a process controller that is a microprocessor (computer) that performs control of the apparatus 10 for treating a substrate; a user interface that is a keyboard through which an operator performs command input operation, etc. to manage the apparatus 10 for treating a substrate, a display that visualizes and displays the operation situation of the apparatus 10 for treating a substrate, etc.; and a memory that stores a control program for performing treatment, which is performed in the apparatus 10 for treating a substrate, under control of the process controller, a program for performing treatment on each component in accordance with various data and treatment conditions, that is, a treatment recipe. Further, the user interface and the memory may be connected to the process controller. The processing recipe may be stored in a memory medium of the memory unit and the memory medium may be a hard disk and may be a portable disc such as a CD-ROM and a DVD, and a semiconductor memory such as a flash memory.

In the embodiment of the present invention, it was described that substrates W are treated in the second chemical liquid bath 142a as an embodiment. However, unlike, substrates W may be treated in any one treatment bath selected from the second rinse bath 142b or the batch treatment baths 141a to 141b of the batch treatment unit 140. Further, unlike the embodiment described above, the configuration of the second chemical liquid bath 142a may be applied to the second rinse bath 142b or the configuration of the second rinse bath 142b may be applied to the second chemical liquid bath 142a.

Further, the configurations of the second chemical liquid bath 142a and the second rinse bath 142b may be equally applied even to another chemical liquid bath or another rinse bath.

In the embodiment described above, it was shown an described that the supporting unit is composed of two supporting parts and the first supporting part 442 and the second supporting part 444 are installed at a lower portion of the first supporting part 442 and the second supporting part 444. However, unlike this, the number of the supporting parts may be variously changed and each of the supporting parts may be installed at a position where it does not interfere with up-down movement of the lifter unit 440.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for treating a substrate, the apparatus comprising:
a first treatment bath having a first accommodation space in which first treatment liquid is accommodated, and performing liquid treatment on a plurality of sheets of substrates;
a second treatment bath having a second accommodation space in which second treatment liquid is accommodated, and performing liquid treatment on the plurality of sheets of substrates;
a supporting unit fixedly installed in the second accommodation space; and
a lifter unit transferring substrates between the first treatment bath and the second treatment bath,
wherein the plurality of sheets of substrates is liquid-treated in a state in which the substrates are supported on the lifter unit in the first treatment bath, and
the plurality of sheets of substrates is liquid-treated in a state in which the substrates are supported on the supporting unit in the second treatment bath.

2. The apparatus of claim 1, wherein when the supporting unit supports the plurality of sheets of substrates in the second accommodation space, the lifter unit is positioned in the second accommodation space.

3. The apparatus of claim 2, wherein when the substrates are liquid-treated with the supporting unit supporting the plurality of sheets of substrates in the second accommodation space, the lifter unit is positioned to be spaced apart from the substrates under the substrates.

4. The apparatus of claim 1, wherein the supporting unit comprises a first supporting part and a second supporting part on each of which a plurality of slots in which the substrates are inserted is formed, and
the first supporting part and the second supporting part are installed opposite to each other.

5. The apparatus of claim 4, wherein regions of the substrates supported by the first supporting part and the second supporting part are positioned outside further than regions of the substrates supported by the lifter unit.

6. The apparatus of claim 1, further comprising a transfer robot transferring the lifter unit between the first treatment bath and the second treatment bath,
wherein the lifter unit is coupled to a side of the transfer robot.

7. The apparatus of claim 6, further comprising a control unit,
wherein the control unit performs control such that the transfer unit conveys the lifter unit, on which the plurality of sheets of substrates is placed, from the first treatment bath to the second treatment bath.

8. The apparatus of claim 7, wherein, in the process in which the lifter unit on which the plurality of sheets of substrates is placed moves down in the second accommodation space in which the second treatment liquid is accommodated, the control unit performs control such that the supporting unit supports the substrates while the lifter unit moves down, and the lifter unit further moves down to be spaced from the substrates, whereby the plurality of sheets of substrates is handed over from the lifter unit to the supporting unit.

9. The apparatus of claim 8, wherein the control unit performs control such that the lifter unit further moves down in the second accommodation space after handing over the plurality of sheets of substrates to the supporting unit and the lifter unit stands by at a lower portion of the second accommodation space when the plurality of sheets of substrates is treated in the second treatment bath.

10. The apparatus of claim 1, wherein the first treatment liquid is a chemical, and
the second treatment liquid is pure water.

11. An apparatus for treating a substrate, comprising:
a treatment bath having an accommodation space accommodating treatment liquid, and treating a plurality of sheets of substrates;
a supporting unit fixedly installed in the accommodation space; and
a transfer robot transferring substrates to the treatment bath,
wherein the transfer robot comprises a lifter unit coupled to a side of the transfer robot and supporting the plurality of sheets of substrates,
the plurality of sheets of substrates is liquid-treated in a state in which the substrates are supported on the supporting unit in the treatment bath, and
the plurality of sheets of substrates is transferred to the treatment bath by the lifter unit before the liquid treatment is performed in the treatment bath.

12. The apparatus of claim 11, wherein when the supporting unit supports the plurality of sheets of substrates in the accommodation space, the lifter unit is positioned in the accommodation space.

13. The apparatus of claim 12, wherein when the substrates are liquid-treated with the supporting unit supporting the plurality of sheets of substrates in the accommodation space, the lifter unit is positioned to be spaced apart from the substrates under the substrates.

14. The apparatus of claim 11, comprising a first supporting part and a second supporting part on each of which a plurality of slots in which the substrates are inserted is formed,
wherein the first supporting part and the second supporting part are installed opposite to each other, and
regions of the substrates supported by the first supporting part and the second supporting part are positioned outside further than regions of the substrates supported by the lifter unit.

15. The apparatus of claim 11, further comprising a control unit,
wherein the control unit performs control such that the transfer robot transfers the lifter unit, on which the plurality of sheets of substrates is placed, to the treatment bath, and the supporting unit supports the substrates while the lifter unit moves down and the lifter unit further moves down to be spaced from the substrates in the process in which the lifter unit moves down in the accommodation space in which the treatment liquid is accommodated, whereby the plurality of sheets of substrates is handed over from the lifter unit to the supporting unit.

16. The apparatus of claim 15, further comprising a control unit,
wherein the control unit performs control such that the lifter unit further moves down in the accommodation space after handing over the plurality of sheets of substrates to the supporting unit and the lifter unit stands by at a lower portion of the accommodation space when the plurality of sheets of substrates is treated in the treatment bath.

17. The apparatus of claim 11, wherein the treatment liquid is pure water.

18. An apparatus for treating a substrate, comprising:
a first treatment bath having a first accommodation space in which first treatment liquid is accommodated, and performing liquid treatment on a plurality of sheets of substrates;
a second treatment bath having a second accommodation space in which second treatment liquid is accommodated, and performing liquid treatment on the plurality of sheets of substrates;
a supporting unit fixedly installed in the second accommodation space; and
a transfer robot transferring substrates between the first treatment bath and the second treatment bath,
wherein the transfer robot comprises a lifter unit coupled to a side of the transfer robot and supporting the plurality of sheets of substrates,
the plurality of sheets of substrates is liquid-treated in a state in which the substrates are supported on the lifter unit in the first treatment bath,
the plurality of sheets of substrates is liquid-treated in a state in which the substrates are supported on the supporting unit in the second treatment bath,
the lifter unit is positioned in the second accommodation space when the supporting unit supports the plurality of sheets of substrates in the second accommodation space,
the supporting unit comprises a first supporting part and a second supporting part on each of which a plurality of slots is formed,
the first supporting part and the second supporting part are installed opposite to each other, and
regions of the substrates supported by the first supporting part and the second supporting part are positioned outside further than regions of the substrates supported by the lifter unit.

19. The apparatus of claim 18, further comprising a control unit,
wherein the control unit performs control such that the transfer robot transfers the lifter unit, on which the plurality of sheets of substrates is placed, from the first treatment bath to the second treatment bath, and the supporting unit supports the substrates while the lifter unit moves down and the lifter unit further moves down to be spaced from the substrates in a process in which the lifter unit, on which the plurality of sheets of substrates is placed, moves down in the second accommodation space in which the second treatment liquid is accommodated, whereby the plurality of sheets of substrates is handed over from the lifter unit to the supporting unit; and
the control unit performs control such that the lifter unit further moves down in the second accommodation space after handing over the plurality of sheets of substrates to the supporting unit and the lifter unit stands by at a lower portion of the second accommodation space when the plurality of sheets of substrates is treated in the second treatment bath.

20. The apparatus of claim 18, wherein the first treatment liquid is a chemical, and
the second treatment liquid is pure water.
